(19) United States
(12) Patent Application Publication
(10) Pub. No.: US 2025/0357181 A1
(43) Pub. Date: Nov. 20, 2025

(54) GROUND RETURN PATH FOR WAFER PROCESS CHAMBER

(71) Applicant: Applied Materials, Inc., Santa Clara, CA (US)

(72) Inventors: Chandrashekar KENCHAPPA, Bangalore (IN); Cory LAFOLLETT, Coeur d' Alene, ID (US); Keith A. MILLER, Mountain View, CA (US)

(21) Appl. No.: 18/663,794

(22) Filed: May 14, 2024

(51) Int. Cl. H01L 21/687; H01J 37/32; H01L 21/263

(52) U.S. Cl. CPC H01L 21/68785; H01J 37/32513; H01J 37/32715; H01L 21/263; H01J 2237/0206

(57) ABSTRACT

The present disclosure describes a method and apparatus for providing a ground return path for a wafer process chamber. A wafer support assembly includes a pedestal that includes a pedestal body, an outer platform coupled to the pedestal body, and a gasket assembly. The pedestal body includes a wafer supporting surface. The outer platform includes a first surface. The gasket assembly is coupled to the first surface and positioned around a perimeter of the pedestal. The gasket assembly includes a tubular gasket and a rod. The rod is disposed within a hollow central region of the tubular gasket. The rod is coupled to the first surface of the outer platform structure.

### BACKGROUND

### Field

Embodiments of the present disclosure generally relate to semiconductor wafer processing systems.

### Description of the Related Art

Semiconductor wafer processing systems perform various processes on semiconductor wafers (e.g., cleaning, etching, deposition, etc.) to form them into semiconductor devices (e.g., integrated circuits). For example, during an etching process, a pedestal of the processing system elevates a wafer into a chamber of the processing system. A plasma is then ignited in the chamber, which bombards portions of the wafer with ions, etching the wafer. To ignite and maintain the plasma, an electric current is sent through the chamber using an electrical circuit. In existing semiconductor wafer processing systems, the electrical circuit is provided by electrically conducting hoops or loops positioned at points on a perimeter or circumference of the pedestal. When the pedestal elevates the wafer into the chamber, the hoops or loops contact the chamber, completing the electrical circuit and providing the grounding path for the current. There remains, however, gaps on the perimeter or circumference of the pedestal where no hoops or loops are attached. Additionally, the hoops or loops are not evenly spaced around the perimeter or circumference. As a result, the generated plasma can leak and escape from the chamber, causing arcs that damage the processing system.

### SUMMARY

The present disclosure describes a wafer processing system that uses a gasket to complete a grounding path. According to an embodiment, a wafer support assembly includes a pedestal that includes a pedestal body, an outer platform coupled to the pedestal body, and a gasket assembly. The pedestal body includes a wafer supporting surface. The outer platform includes a first surface. The gasket assembly is coupled to the first surface and positioned around a perimeter of the pedestal. The gasket assembly includes a tubular gasket and a rod. The rod is disposed within a hollow central region of the tubular gasket. The rod is coupled to the first surface of the outer platform structure.

According to another embodiment, a method for processing a wafer includes moving a pedestal such that a portion of the pedestal is positioned within a process volume of a process chamber and such that the pedestal brings a gasket assembly positioned around a perimeter of the pedestal into contact with a bottom surface of a process kit. The method also includes sending an electrical current through the process volume to ignite a plasma in the process volume. The gasket assembly provides a grounding path for the electrical current.

According to another embodiment, a wafer processing system includes a process chamber, a pedestal, and an annular gasket assembly. The process chamber includes a process volume. The pedestal includes a pedestal body and an outer platform positioned around the pedestal body. The pedestal elevates a wafer on the pedestal body into the process volume. The annular gasket assembly is coupled to the outer platform such that the gasket assembly is positioned around the pedestal body. When the pedestal elevates the wafer into the process volume, the outer platform brings the gasket assembly into contact with a process kit such that the gasket assembly provides a grounding path for an electrical current in the process volume.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 illustrates an example wafer processing system, according to one or more embodiments of the disclosure.

FIG. 2 illustrates the wafer processing system of FIG. 1 elevating a wafer.

FIG. 3 illustrates the wafer processing system of FIG. 1 elevating a wafer.

FIG. 4 illustrates a portion of the wafer processing system of FIG. 1, according to one or more embodiments of the disclosure.

FIG. 5 illustrates a portion of the wafer processing of FIG. 1, according to one or more embodiments of the disclosure.

FIG. 6 illustrates a portion of the wafer processing system of FIG. 1, according to one or more embodiments of the disclosure.

FIG. 7 illustrates an example gasket in the wafer processing system of FIG. 1, according to one or more embodiments of the disclosure.

FIG. 8 is a flowchart of an example method performed by the wafer processing system of FIG. 1, according to one or more embodiments of the disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure describes a gasket used to provide a grounding path for radio frequency (RF) current generated during a plasma process performed in a semiconductor wafer processing chamber. Generally, the gasket is positioned on a pedestal that elevates a semiconductor wafer into the chamber. A rod is positioned within the gasket, and the gasket and the rod are coupled to the pedestal by a fastener (e.g., screw, bolt, rod, etc.) extending into the gasket and the rod. The gasket is formed using an electrically conductive material (e.g. metal), and the gasket has an annular shape and is positioned around a perimeter or circumference of the pedestal. When the pedestal elevates the semiconductor wafer into the chamber, the pedestal also brings the gasket into contact (e.g., physical and/or electrical contact) with a bottom surface of a portion of a process kit disposed within the chamber. As a result, the gasket completes an electrical circuit and provides a grounding path for the RF current generated in the chamber when the semiconductor wafer is exposed to an RF generated plasma during processing.

In certain embodiments, the gasket reduces the gaps around the perimeter or circumference of the pedestal and thus is used to separate the plasma processing region disposed over a wafer and a lower portion of the chamber. As a result, the gasket prevents the generated plasma from leaking or escaping from the chamber, which reduces arcing. Thus, the gasket may prevent damage to the wafer processing system caused by arcing.

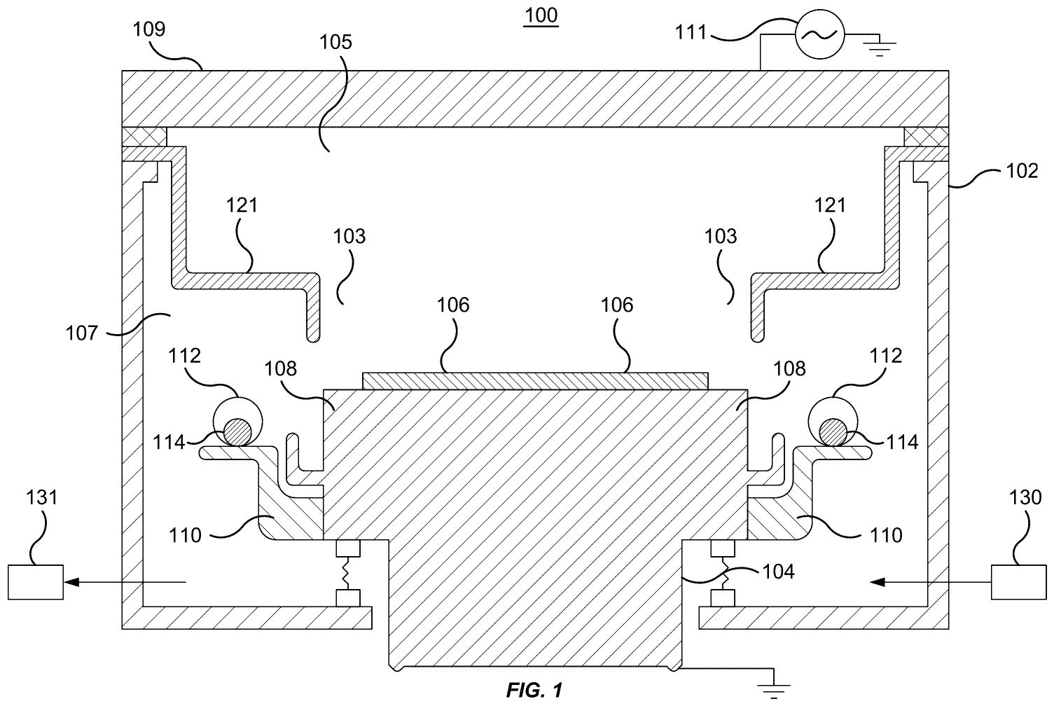

FIG. 1 illustrates an example wafer processing system 100. Generally, FIG. 1 shows a cross section of the system 100. As seen in FIG. 1, the system 100 includes a chamber 102 and a pedestal 104. Generally, the pedestal 104 and a pedestal actuator (not shown) elevates a semiconductor wafer into an upper portion of the chamber 102 for processing. Any type of process may be performed on the wafer in the chamber 102. In one example, any number of processes may be performed using the chamber 102, such as preclean, chemical vapor deposition (CVD), plasma enhanced chemical vapor deposition (PECVD), physical vapor deposition (PVD), atomic layer deposition (ALD), decoupled plasma nitridation (DPN), rapid thermal processing (RTP), ashing, annealing, and etching, or any process utilized in semiconductor device fabrication. For example, during a PVD or an etching process, a plasma may be ignited in a processing volume 105 of the chamber, and the plasma may bombard portions of the wafer with ions generated in the plasma, which etches the wafer. An electrical circuit is formed through the pedestal 104 when the pedestal 104 provides a grounding path for the RF generated current created by delivering an RF signal to an electrode 109 (e.g., PVD target, CVD showerhead, or chamber lid) by a power source 111 to form the plasma. However, in some embodiments, the power source 111 can be a DC or RF power source, and in some applications, the electrode powered by the power source 111 can be disposed within the pedestal 104.

The chamber 102 may be a metallic structure that defines a volume that includes a process volume 105 and a lower region 107. The chamber 102 includes an opening 103 formed in a process kit component 121 disposed within the chamber 102. The chamber 102 may include other openings through which a gas is provided into the chamber by a gas source 130 or evacuated from the chamber 102 by a vacuum pump 131. During a process (e.g., an etching process), an RF current may be directed to a gas disposed in processing volume 105 of the chamber 102 to form a plasma in the chamber 102.

The pedestal 104 may move to position a wafer 106 (e.g., a semiconductor wafer) into the processing volume 105 of the chamber 102. As seen in FIG. 1, the wafer 106 may be positioned on the pedestal 104 when the pedestal 104 is in a lowered state by use of a robotic device (not shown). The pedestal 104 may then move towards the processing volume 105 region of the chamber 102 and thus elevate the wafer 106 through the opening 103 and into the processing volume 105 of the chamber 102. Portions of the pedestal 104 may also move through the opening 103 and into the chamber 102.

As seen in FIG. 1, the pedestal 104 includes an inner platform 108 (which may also be referred to as a pedestal body) and an outer platform 110. The wafer 106 may be positioned on a surface of the inner platform 108, and portions of the inner platform 108 may move through the opening 103 and into the processing volume 105 of the chamber 102. The outer platform 110 is coupled to and positioned radially outward from the inner platform 108. As a result, the outer platform 110 may encircle or surround the inner platform 108. In the example of FIG. 1, the outer platform 110 does not move through the opening 103 and into the processing volume 105 of the chamber 102 when the pedestal 104 elevates the wafer 106.

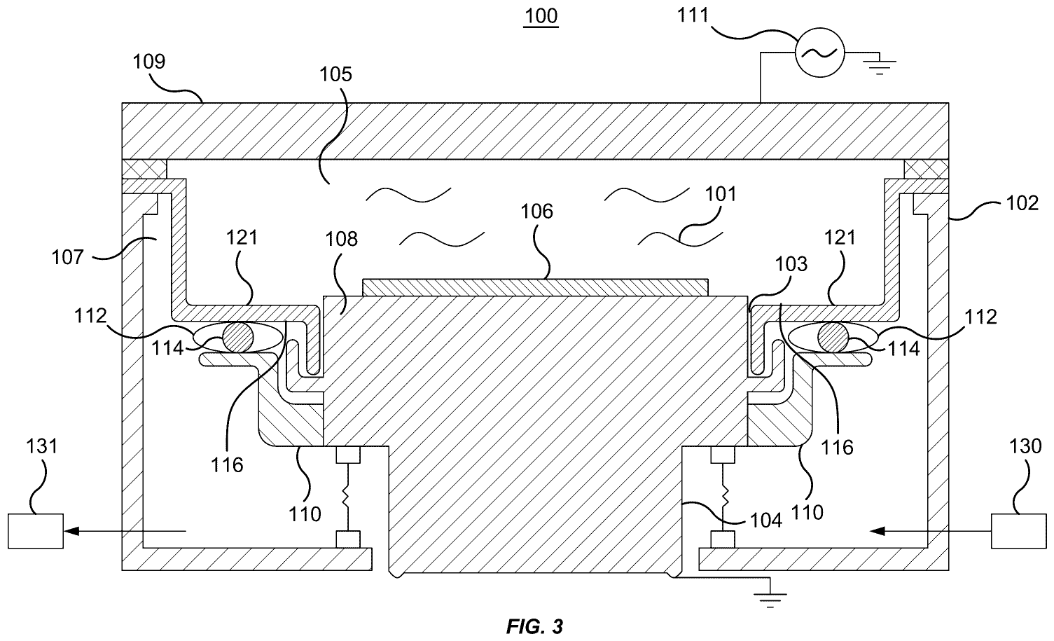

A gasket 112 is positioned on a surface of the outer platform 110. The gasket 112 and the outer platform 110 may be formed using electrically conducting materials (e.g., stainless steel, copper, silver, nickel, etc.). The gasket 112 may be a tubular structure with a hollow central region. When the pedestal 104 moves to elevate the wafer 106 into the processing volume 105 of the chamber 102, the outer platform 110 will move to bring the gasket 112 into contact (e.g., physical and/or electrical contact) with a portion of the chamber 102, which completes an electrical circuit between the chamber 102 and the pedestal 104. The gasket 112 may be in contact with a bottom surface of a component within the process kit 121 (e.g., shield) of the chamber 102 that is disposed around the perimeter or circumference of the pedestal 104. As a result, the gasket 112 may prevent the plasma 101 (shown in FIG. 3) from leaking or escaping from the processing volume 105 of the chamber 102 during processing, which reduces arcing. When the pedestal 104 moves away from the processing volume 105 of the chamber 102 to remove the wafer 106 from the chamber 102, the outer platform 110 will move the gasket 112 away from the process kit 121 of the chamber 102 such that the gasket 112 does not contact the surface of the process kit 121 of the chamber 102.

A rod 114 is positioned within the gasket 112 (e.g., in the hollow central region of the gasket 112). The rod 114 may be formed using a hard or rigid material (e.g., stainless steel). The rod 114 provides structural and/or mechanical support for the gasket 112 when it is mounted on the surface of the outer platform 110. For example, when the outer platform 110 moves to bring the gasket 112 into contact with the chamber 102, the gasket 112 may be compressed between the process kit 121 and the outer platform 110. The rod 114 may limit the amount by which the gasket 112 compresses as the gasket 112 is urged against a surface of the process kit 121 by the actuator used to provide motion to the pedestal 104. For example, the rod 114 may prevent the gasket 112 from compressing to a smaller height than the thickness (e.g., diameter) of the rod 114 in the direction of motion of the pedestal 104 (e.g., vertical direction). In some embodiments, both the gasket 112 and the rod 114 are coupled to the outer platform 110. For example, a fastener (e.g., a screw, bolt, rod, strap, etc.) may extend from the outer platform 110, into the gasket 112, and into the rod 114 to secure the gasket 112 and the rod 114 to a surface of the outer platform 110. The gasket 112 and the rod 114 form a gasket assembly.

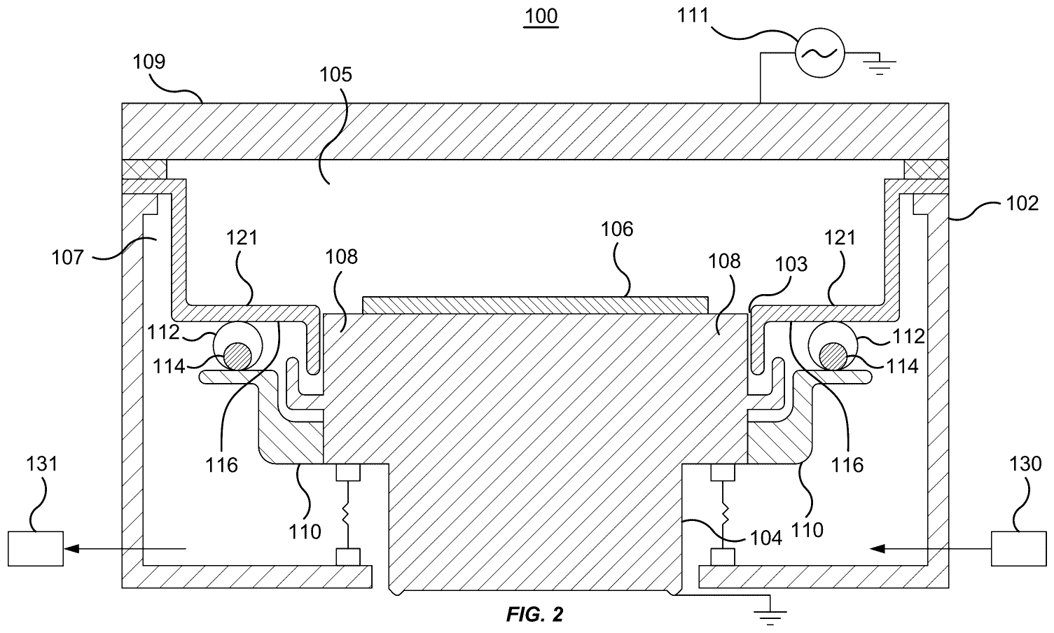

FIG. 2 illustrates the wafer processing system 100 of FIG. 1 elevating the wafer 106. As seen in FIG. 2, the pedestal 104 moves towards the processing volume 105 of the chamber 102 to elevate the wafer into the opening 103. As the pedestal 104 moves towards the processing volume 105, the outer platform 110 brings the gasket 112 into contact with a bottom surface 116 of the process kit 121 of the chamber 102. This contact may complete an electrical circuit and provide a grounding path for the RF current generated in the chamber 102 during processing. As a result, RF current in the chamber 102 may flow through a plasma 101 (shown in FIG. 3) formed in the chamber 102 during processing, into the walls of the process kit 121, into the gasket 112 through the bottom surface of the process kit 121, and through the gasket 112 into a conductive portion of the pedestal 104 that is coupled to ground. In certain embodiments, because the gasket 112 is positioned around a perimeter or circumference of the pedestal 104 and the outer platform 110, the gasket 112 reduces or eliminates gaps around the bottom surface 116 of the process kit 121 of the chamber 102. As a result, the gasket 112 prevents the plasma from leaking from processing volume 105 of the chamber 102, which reduces arcing.

FIG. 3 illustrates the wafer processing system 100 of FIG. 1 in which the wafer 106 is elevated to a processing position. As seen in FIG. 3, the pedestal 104 has elevated the wafer 106 and a portion of the pedestal 104/inner platform 108 into the processing volume 105. In this position, the wafer 106 may be processed inside the processing volume 105. For example, RF power may be provided to the gas disposed in the processing volume 105 to ignite a plasma 101. Ions within the plasma 101 may be directed (e.g., pulsed) towards the wafer 106 to etch the wafer 106 by use of a bias applied to an electrode (not shown) disposed within the inner platform 108 by a DC or RF bias source (not shown).

Additionally, as seen in FIG. 3, the pedestal 104 has moved further into the chamber 102 relative to the position of the pedestal 104 in FIG. 2. As a result, the gasket 112 has compressed relative to the state of the gasket 112 in FIG. 2. The ability of the gasket 112 to be compressed can prevent the gasket 112 from causing damage to portions of the chamber 102 or the pedestal 104 due to the repeated cycling of the position of the pedestal 104 into the processing volume 105. In the example of FIG. 3, the gasket 112 has compressed between the bottom surface 116 of the process kit 121 and the outer platform 110. The gasket 112 has compressed to the height or diameter of the rod 114. The rod 114 prevents the gasket 112 from further compressing past the height or diameter of the rod 114.

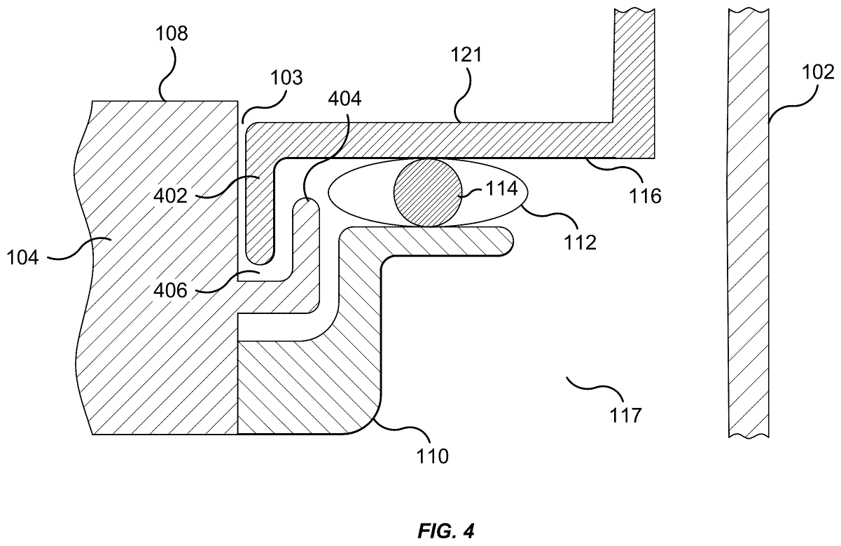

FIG. 4 illustrates a portion of the wafer processing system 100 of FIG. 1. Generally, FIG. 4 shows the gasket 112 compressed between the bottom surface 116 of the process kit 121 and the outer platform 110. The gasket 112 has compressed to the height or diameter of the rod 114. The rod 114 prevents the gasket 112 from further compressing, which provides resistance that prevents the pedestal 104 from further moving towards the chamber 102.

As seen in FIG. 4, the process kit 121 includes a lip 402 and the inner platform 108 includes a lip 404. The lip 402 defines the opening 103 of the chamber 102. The lip 404 extends from the inner platform 108 and curves towards the bottom surface 116 of the process kit 121. The rod 114 may stop the pedestal 104 from further moving towards the upper portion of the chamber 102 such that there is a gap 406 between a lower end of the lip 402 and the lip 404. As a result, the rod 114 may stop the pedestal 104 before the lip 404 contacts the lip 402.

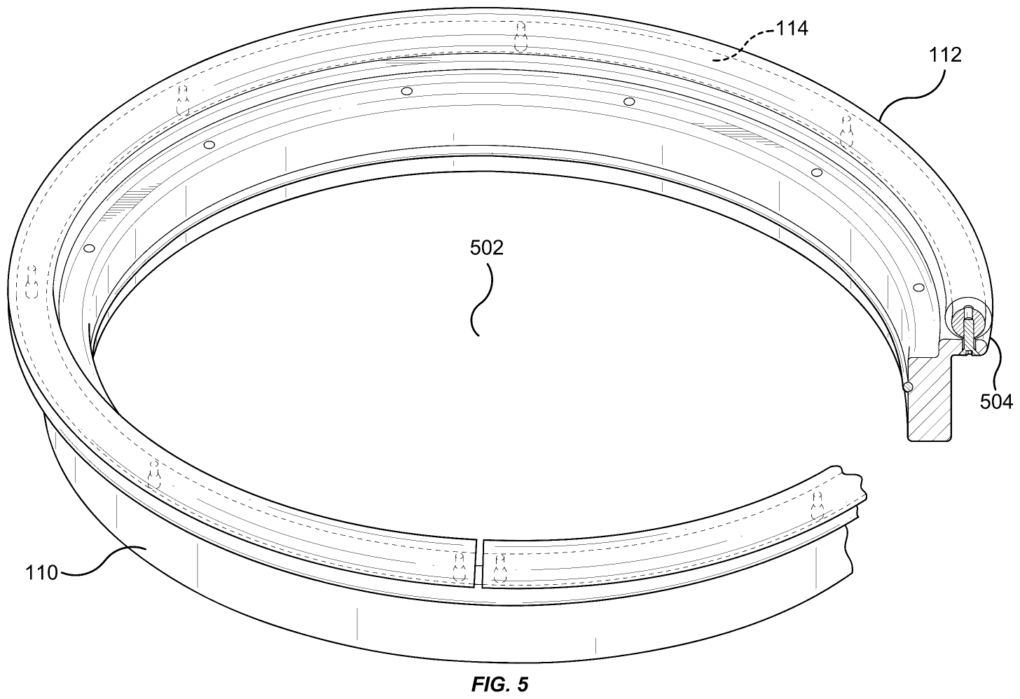

FIG. 5 illustrates a partial section view of a portion of the wafer processing system 100 of FIG. 1. Generally, FIG. 5 shows an embodiment of the outer platform 110 of the pedestal 104. As seen in FIG. 5, the outer platform 110 is annular and defines an aperture 502. The inner platform 108 of the pedestal 104 may extend through the aperture 502 when the outer platform 110 is positioned around the inner platform 108. In the example of FIG. 5, the outer platform 110 is circular in shape. It is understood, however, that the outer platform 110 may have any shape (e.g., rectangular, triangular, etc.).

The gasket 112 is positioned around a perimeter or circumference 504 of the outer platform 110. The gasket 112 is considered formed around the perimeter or circumference 504 of the platform 110 if the gasket 112 is positioned radially outwards and around the inner platform 108 when the inner platform 108 extends through the aperture 502. Stated differently, portions of the outer platform 110 may extend radially outwards and beyond the gasket 112, and the gasket 112 would still be considered positioned around the perimeter or circumference 504 of the outer platform 110. Additionally, as seen in FIG. 5, the gasket 112 also has an annular shape like the outer platform 110.

Additionally, the rod 114 is positioned around the perimeter or circumference 504 of the outer platform 110. The rod 114 is also positioned within the gasket 112. As discussed previously, the rod 114 provides structural and mechanical support for the gasket 112. For example, the rod 114 may prevent the gasket 112 from compressing past the height or diameter of the rod 114.

As seen in FIG. 5, the gasket 112 is also arranged in a circular shape around the perimeter or circumference 504 of the outer platform 110. The gasket 112 may be cut or formed into any length so as to cover the entirety or near the entirety of the perimeter or circumference 504 of the outer platform 110. As a result, when the outer platform 110 moves the gasket 112 into contact with the bottom surface 116 of the process kit 121, the gasket 112 forms a circular, conductive path from the chamber 102 to an electrical ground coupled to a portion of the chamber 102 and/or pedestal 104. The circular shape of the gasket 112 may reduce or eliminate arcing caused by the plasma escaping radially from the outer platform 110.

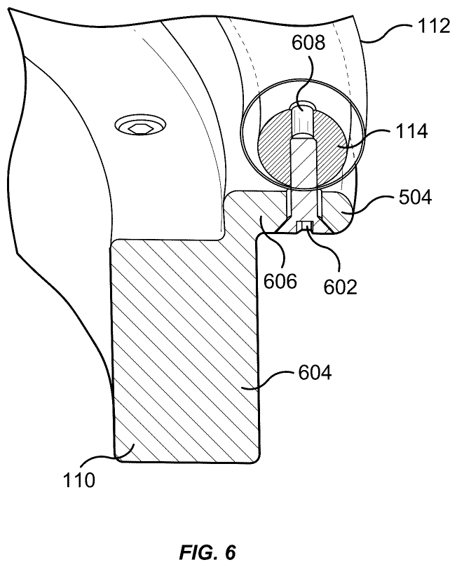

FIG. 6 illustrates a portion of the wafer processing system 100 of FIG. 1. Generally, FIG. 6 shows the gasket 112 and the rod 114 coupled to the outer platform 110. As seen in FIG. 6, the gasket 112 and the rod 114 are positioned around a perimeter or circumference 504 of the outer platform 110. A fastener 602 (e.g., a screw) extends from the outer platform 110, into the gasket 112, and into the rod 114. The fastener 602 may also extend through the outer platform 110. For example, holes 608 may be formed in the outer platform 110, gasket 112, and rod 114. The holes 608 may be sized and shaped to accommodate the fastener 602. In this manner, the fastener 602 couples the gasket 112 and the rod 114 to the outer platform 110 and prevents the gasket 112 and the rod 114 from separating from the outer platform 110.

Any number of fasteners 602 may be used to attach the gasket 112 and the rod 114 to the outer platform 110. These fasteners 602 may be positioned around the perimeter or circumference 504 of the outer platform 110. The fasteners 602 may be evenly spaced around the perimeter or circumference 504. In some embodiments, the fasteners 602 prevent the gasket 112 and the rod 114 from shifting or moving when the outer platform 110 compresses the gasket 112 against the chamber 102. As a result, the fasteners 602 hold the gasket 112 and rod 114 in place to maintain the grounding path for the electrical current in the chamber 102.

As seen in FIG. 6, the outer platform 110 includes a body 604 and a ridge 606. The ridge 606 is positioned on the body 604 and extends radially outwards from the body 604. The ridge 606 may form the perimeter or circumference 504 of the outer platform 110. The gasket 112 and the rod 114 are positioned on the ridge 606. The fastener 602 may extend through the ridge 606 and into the gasket 112 and rod 114.

In an example implementation, the outer platform 110 may have a diameter greater than the diameter of the substrate, such as about 15 inches for a 300 mm wafer. In one example, the rod 114 may have a diameter of between about 5 mm and about 10 mm, and the gasket 112 may have a diameter of between about 8 mm and 30 mm. As a result, the gasket 112 may compress approximately between about 3 mm and 20 mm before the rod 114 stops the gasket 112 from further compressing.

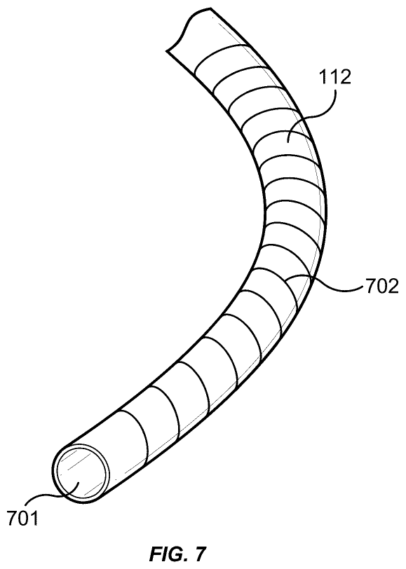

FIG. 7 illustrates an example gasket 112 in the wafer processing system 100 of FIG. 1. As seen in FIG. 7, the gasket 112 may have a tubular shape. The rod 114 may be positioned in the hollow central region 701 of the tube. The gasket 112 may be made of an electrically conductive material (e.g., stainless steel, copper, silver, nickel, etc.). Additionally, as seen in FIG. 7, the body of the gasket 112 may include a spiraled groove that spirals along a length of the gasket 112. The groove 702 improves the flexibility of the gasket 112, which may make it easier for the gasket 112 to be positioned around the perimeter or circumference 504 of the outer platform 110 and for the gasket 112 to compress. The groove 702 may be sized such that a generated plasma is unlikely to escape through the groove 702 when the gasket 112 is brought in contact with the process kit 121 of the chamber 102. In other words, the groove 702 may be sized to form a dark-space gap to prevent plasma leakage.

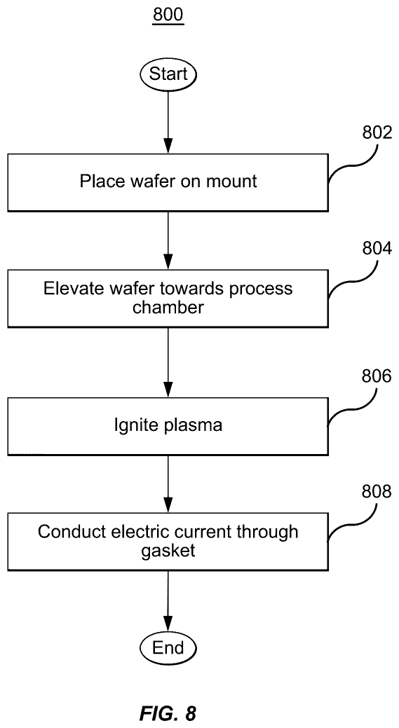

FIG. 8 is a flowchart of an example method 800 performed by the wafer processing system 100 of FIG. 1. In particular embodiments, by performing the method 800, the system 100 processes a wafer 106.

At block 802, a wafer 106 is placed or positioned on the pedestal 104. For example, the wafer 106 may be placed on the upper surface of the inner platform 108 of the pedestal 104. The pedestal 104 is positioned such that the pedestal 104 is outside the processing volume 105 of the chamber 102. At block 804, the pedestal 104 elevates the wafer 106 towards the processing volume 105 of the process chamber 102. For example, the pedestal 104 may move towards the processing volume 105 and through an opening 103 in the process kit 121. The inner platform 108 may move through the opening 103 and into the processing volume 105, which positions the wafer 106 within the processing volume 105.

In block 806, the system 100 ignites a plasma within the chamber 102. For example, gas may be pumped into the chamber 102, and RF power is provided to the processing volume 105. The RF power energizes the gas, igniting the plasma. In block 808, the gasket 112 conducts the RF current from the process kit 121 and through the gasket 112. In this manner, the gasket 112 provides a grounding path for the RF current in the chamber 102.

The gasket 112 may be positioned on the outer platform 110 of the pedestal 104. The outer platform 110 may be annular and may define an aperture 502 through which the inner platform 108 extends. The gasket 112 may be positioned on a perimeter or circumference 504 of the outer platform 110, around the aperture 502 and the inner platform 108. When the pedestal 104 elevates the wafer 106 into the processing volume 105, the outer platform 110 may move the gasket 112 towards the process kit 121 and bring the gasket 112 into contact (e.g., physical and/or electrical contact) with the bottom surface 116 of the process kit 121. The outer platform 110 may compress the gasket 112 between the process kit 121 and the outer platform 110. When the gasket 112 contacts the process kit 121, the gasket 112 completes the electrical circuit for the RF current in the processing volume 105 and provides the grounding path for the RF current. During the processing of the wafer 106, the current may conduct through the process kit 121 and the gasket 112 to ground. Because the gasket 112 is positioned around the perimeter or circumference 504 of the outer platform 110, the gasket 112 may prevent or make it unlikely for the plasma to leak or escape, which reduces arcing.

The rod 114 may be positioned in the gasket 112 and around the perimeter or circumference 504 of the outer platform 110. The rod 114 may be more rigid than the gasket 112. As a result, the rod 114 may prevent the gasket 112 from compressing beyond the height or diameter of the rod 114. In some embodiments, the rod 114 prevents the pedestal 104 from moving so close to the process kit 121 that the pedestal 104 contacts the process kit 121.

Fasteners 602 may attach the gasket 112 and the rod 114 to the outer platform 110. For example, screws, bolts, rods, straps, and/or other types of fasteners may extend from the outer platform 110, into the gasket 112, and into the rod 114. The fasteners 602 may be spaced around the perimeter or circumference 504 of the outer platform 110. In this manner, the fasteners 602 prevent the gasket 112 and rod 114 from separating from the outer platform 110. Additionally, the fasteners 602 may prevent the gasket 112 and rod 114 from shifting or moving when the outer platform 110 compresses the gasket 112 against the chamber 102.

In summary, the gasket 112 is used to provide a grounding path for RF current generated in the semiconductor wafer processing chamber 102. Generally, the gasket 112 is positioned on a pedestal 104 that elevates a semiconductor wafer 106 into a processing volume 105 of the chamber 102. The rod 114 is positioned within the gasket 112, and the gasket 112 and the rod 114 are coupled to the pedestal 104 by a fastener 602 (e.g., screw, bolt, rod, etc.) extending into the gasket 112 and the rod 114. The gasket 112 is formed using an electrically conductive material (e.g. metal), and the gasket 112 has an annular shape and is positioned around a perimeter or circumference 504 of the pedestal 104. When the pedestal 104 elevates the semiconductor wafer 106 into the chamber 102, the pedestal 104 also brings the gasket 112 into contact (e.g., physical and/or electrical contact) with a bottom surface 116 of the process kit 121. As a result, the gasket 112 completes an electrical circuit and provides a grounding path for the RF current generated in the chamber 102 when the semiconductor wafer 106 is processed.

While the foregoing is directed to embodiments of the present disclosure, other and further embodiments of the disclosure may be devised without departing from the basic scope thereof, and the scope thereof is determined by the claims that follow.

What is claimed is:

1. A wafer support assembly comprising:
a pedestal comprising:
a pedestal body comprising a wafer supporting surface;
an outer platform structure coupled to the pedestal body, wherein the outer platform comprises a first surface; and
a gasket assembly coupled to the first surface and positioned around a perimeter of the pedestal, wherein the gasket assembly comprises a tubular gasket and a rod, wherein the rod is disposed within a hollow central region of the tubular gasket, and wherein the rod is coupled to the first surface of the outer platform structure.

2. The wafer processing system of claim 1, wherein the rod is positioned around the perimeter of the pedestal.

3. The wafer processing system of claim 2, further comprising a plurality of fasteners extending into the tubular gasket and the rod to couple the gasket assembly to the pedestal.

4. The wafer processing system of claim 2, wherein the tubular gasket is arranged to compress.

5. The wafer processing system of claim 4, wherein the rod resists compression of the tubular gasket.

6. The wafer processing system of claim 2, wherein the rod prevents a portion of the pedestal from contacting a process kit when the pedestal moves.

7. The wafer processing system of claim 1, wherein the tubular gasket defines a spiraled groove along a surface of the tubular gasket.

8. A method for processing a wafer, the method comprising:
moving a pedestal such that a portion of the pedestal is positioned within a process volume of a process chamber and such that the pedestal brings a gasket assembly positioned around a perimeter of the pedestal into contact with a bottom surface of a process kit; and
sending an electrical current through the process volume to ignite a plasma in the process volume, wherein the gasket assembly provides a grounding path for the electrical current.

9. The method of claim 8, wherein the gasket assembly comprises a tubular gasket and a rod positioned within a hollow central region of the tubular gasket and around the perimeter of the pedestal.

10. The method of claim 9, wherein a plurality of fasteners extend into the tubular gasket and the rod to couple the gasket assembly to the pedestal.

11. The method of claim 9, wherein the tubular gasket compresses when the pedestal brings the tubular gasket into contact with the bottom surface of the process kit.

12. The method of claim 11, wherein the rod resists compression of the tubular gasket.

13. The method of claim 9, wherein the rod prevents a portion of the pedestal from contacting the process kit when the pedestal moves.

14. The method of claim 8, wherein the gasket assembly defines a spiraled groove along a surface of the gasket assembly.

15. A wafer processing system comprising:
a process chamber comprising a process volume;
a pedestal comprising a pedestal body and an outer platform positioned around the pedestal body, wherein the pedestal is arranged to elevate a wafer on the pedestal body into the process volume; and
an annular gasket assembly coupled to the outer platform such that the gasket assembly is positioned around the pedestal body, wherein when the pedestal elevates the wafer into the process volume, the outer platform brings the gasket assembly into contact with a process kit such that the gasket assembly provides a grounding path for an electrical current in the process volume.

16. The wafer processing system of claim 15, wherein the gasket assembly comprises a tubular gasket and a rod positioned within a hollow central region of the tubular gasket and positioned around a perimeter of the pedestal.

17. The wafer processing system of claim 16, further comprising a plurality of fasteners extending into the tubular gasket and the rod to couple the gasket assembly to the outer platform.

18. The wafer processing system of claim 16, wherein the tubular gasket is arranged to compress.

19. The wafer processing system of claim 18, wherein the rod resists compression of the tubular gasket.

20. The wafer processing system of claim 16, wherein the rod prevents a portion of the pedestal body from contacting the process kit when the pedestal elevates the wafer into the process volume.
